(19) United States
(12) Patent Application Publication
(10) Pub. No.: US 2026/0227458 A1
(43) Pub. Date: Aug. 6, 2026

(54) MODEL AGNOSTIC COMPONENT POWER SHARING

(71) Applicant: International Business Machines Corporation, Armonk, NY (US)

(72) Inventors: David Lee McClintock, Austin, TX (US); Eric B. Swenson, Pine Island, MN (US); Lee N. Helgeson, ROCHESTER, MN (US)

(73) Assignee: International Business Machines Corporation, Armonk, NY (US)

(21) Appl. No.: 19/044,860

(22) Filed: Feb. 4, 2025

(51) Int. Cl. G01R 31/40

(52) U.S. Cl. CPC G01R 31/40

(57) ABSTRACT

An embodiment monitors a set of power supply units. The embodiment disables, upon detecting that the set of power supply units comprise a non-homogenous set of power supply units, a first power sharing circuit, the first power sharing circuit configured to perform a first load balancing function among a homogenous set of supply units. The embodiment activates a second power sharing circuit, the second power sharing circuit configured to perform a second load balancing function among the non-homogeneous set of power supply units.

### BACKGROUND

The present invention relates generally to power management. More particularly, the present invention relates to a method, system, circuit, and computer program for model agnostic component power sharing.

Power management includes the management of power supply systems. A power management controller is an electronic device or integrated circuit that may be configured for monitoring, regulating, and controlling the power distribution within a system or device. A power management controller typically interfaces with various components such as power supply units, sensors, and communication interfaces to coordinate utilization of power resources, optimize performance, and maintain system stability. Power management controllers may employ various algorithms, logic circuits, and communication protocols to manage power consumption, implement power-sharing strategies, and respond to dynamic changes in power requirements and/or available resources.

A power management system may employ a power management controller to accomplish power sharing in order to maintain balanced load distribution. Load sharing is the process of distributing a load or demand for power evenly among multiple resources or systems. In the context of electrical systems, load sharing may involve the distribution of power among multiple generators, power sources, or energy storage devices proportionally to meet the demand efficiently without overuse.

### SUMMARY

The illustrative embodiments provide for model agnostic component power sharing. An embodiment includes monitoring a set of power supply units. The embodiment also includes disabling, upon detecting that the set of power supply units comprises a non-homogenous set of power supply units, a first power sharing circuit, the first power sharing circuit configured to perform a first load balancing function among a homogenous set of power supply units. The embodiment also activates a second power sharing circuit, the second power sharing circuit configured to perform a second load balancing function among the non-homogeneous set of power supply units.

An embodiment includes a computer usable program product. The computer usable program product includes a computer-readable storage medium, and program instructions stored on the storage medium.

An embodiment includes a computer system. The computer system includes a processor, a computer-readable memory, and a computer-readable storage medium, and program instructions stored on the storage medium for execution by the processor via the memory.

### BRIEF DESCRIPTION OF THE DRAWINGS

The novel features believed characteristic of the invention are set forth in the appended claims. The invention itself, however, as well as a preferred mode of use, further objectives, and advantages thereof, will best be understood by reference to the following detailed description of the illustrative embodiments when read in conjunction with the accompanying drawings, wherein:

FIG. 1 depicts a block diagram of a computing environment in accordance with an illustrative embodiment;

FIG. 2 depicts a block diagram of an example system environment in accordance with an illustrative embodiment;

FIG. 3 depicts a block diagram of an example power management controller module in accordance with an illustrative embodiment;

FIG. 4A depicts a block diagram of an example state machine in accordance with an illustrative embodiment;

FIG. 4B depicts a block diagram of an example power management process in accordance with an illustrative embodiment;

FIG. 5 depicts a circuit diagram of an example power management circuit in accordance with an illustrative embodiment;

FIG. 6 depicts a block diagram of an example system architecture in accordance with an illustrative embodiment;

FIG. 7 depicts a block diagram of an example system architecture in accordance with an illustrative embodiment;

FIG. 8 depicts a block diagram of an example system architecture in accordance with an illustrative embodiment;

FIG. 9 depicts a block diagram of an example system architecture in accordance with an illustrative embodiment;

FIG. 10 depicts a flowchart of an example service routine, in accordance with an illustrative embodiment; and

FIG. 11 depicts a flowchart of an example process for power management, in accordance with an illustrative embodiment.

### DETAILED DESCRIPTION

Currently existing power sharing systems and techniques do not provide cross compatibility between different energy storage unit model types. For example, if a user attempts to cross plug different power supply units of different wattages, the user may be required to first power down the system before the user can replace a power supply unit by cross plugging different wattage power supplies during replacement procedure.

Accordingly, currently existing systems and methods do not allow cross plugging power supplies from different OEMs or different models of power supplies. Powering down a system to perform a component replacement may be highly disruptive to a system or organization, especially when maintaining an uninterrupted power supply is an important aspect for a system or organization. Accordingly, there is often a high-cost impact caused by the inability to continuously run a workload while a power supply is being replaced.

Further, load sharing amongst dissimilar power supplies can cause instability and imbalance of the power subsystem, potentially causing the datacenter equipment to unexpectedly shutdown. This disclosure describes a method and a circuit device to disable “load sharing” of dissimilar power supplies in datacenter equipment, and thus prevent an unexpected shutdown due to power subsystem instability caused by unbalanced load sharing of dissimilar power supply models.

Currently there is no way to replace or “swap” a power supply unit without potentially interrupting power supply different power supply units while meanwhile preserving effective load sharing. These current limitations make it impossible to provide uninterrupted service in many instances. As a result, current efforts in this regard are inefficient and ineffective due to the current inability to hot swap and perform effective load sharing between components of a different type or from a different manufacturer.

The present disclosure addresses the deficiencies described above by providing a process (as well as a system, method, machine-readable medium, etc.) that develops a model agnostic power sharing system, method, and electronic circuit device that disables automatic power sharing between different power supply units and enables power supply sharing between different power supply units via a separate circuit configuration.

The illustrative embodiments provide for model agnostic power sharing. Power sharing as referred to herein refers to the process of distributing a load demand among a plurality of power supply units. Further, the term “power supply unit” refers to an electronic device that converts electrical power from a power source into the specific voltage, current, and frequency required to power electronic devices or systems. PSUs typically consist of components such as transformers, rectifiers, filters, and voltage regulators to provide stable power delivery to the connected load. Some embodiments disclosed herein describe the power supply unit as a common redundant power supply; however, use of this example is not intended to be limiting but is instead used for descriptive purposes only. Instead, the power supply unit can include elements of one or more of various types of power supply units.

As used throughout the present disclosure, the term “hot swapping” refers to the capability and/or process of replacing or adding components to a system without the need to power down or interrupt the operation of the system. This feature allows for the insertion or removal of hardware components, such as power supply units, storage drives, network cards, etc., while the system remains powered on and operational.

As used throughout the present disclosure, the term “power management controller” (or simply “PMC”) refers to an integrated circuit or component configured for monitoring, controlling, and/or optimizing power usage within a system or device. A power management controller regulates the distribution of electrical power to various components, manages power-saving features, and provides efficient utilization of energy resources. A power management controller may incorporate functions such as voltage regulation, current monitoring, thermal management, and power sequencing to maintain load sharing, system stability, and prevent overloading.

As used throughout the present disclosure, the term “common redundant power supply” (or simply “CRPS”) refers to a type of power supply unit (PSU) designed to be modular, compact, and compatible across multiple systems or configurations. CRPS are often used in data centers or server environments. However, use of this example is not meant be limiting, but is instead used for descriptive purposes only. A CRPS may be utilized for any system or application where it may be suitable, as would be known to one or ordinary skill in the art.

As used throughout the present disclosure, non-homogenous CRPS replacement refers to replacing a failed CRPS unit with one that may not be identical in capacity or specifications. For example, a system originally designed with 1200W CRPS units might have one replaced with an 800W unit. While the system can still function, load sharing might be imbalanced, with the non-homogeneous CRPS contributing less power or operating under different conditions.

As used throughout the present disclosure, a fully redundant, homogenous-CRPS load share system architecture refers to a setup where multiple identical CRPS units are used in parallel to share the electrical load (load sharing). Each unit contributes equally or proportionally to the total power demand, ensuring balanced operation and extended lifespan of the units. Redundancy ensures that if one CRPS fails, the remaining units seamlessly take over the load.

As used throughout the present disclosure, the term “model agnostic” refers to the characteristic of a system or approach being able to operate independently of specific models or types. In the context of the present disclosure, model agnostic refers to the characteristic of a system being compatible with any available suitable power supply unit, regardless of the model, type, or manufacturer. Embodiments of the present disclosure enable a system to accommodate and function effectively with a wide range of PSU types, models, or combinations without being dependent on specific PSU specifications. This model agnostic approach enables the system to integrate and operate with diverse PSU configurations, regardless of the manufacturer, capacity, or design differences.

As used throughout the present disclosure, the term “ISHARE” refers to a feature of a power management system that enables multiple CRPS to be connected for load sharing. Accordingly, ISHARE is a functionality or feature in power management systems that enables power supply units (PSUs) to share power resources in a coordinated and synchronized manner. The ISHARE functionality allows multiple PSUs to work together to provide power to a system or device, ensuring efficient distribution of power, load balancing, and redundancy in case of PSU failure. ISHARE typically involves, control mechanisms, and power-sharing algorithms that facilitate the coordinated operation of multiple PSUs to optimize power delivery and system reliability.

As used throughout the present disclosure, the term “buss voltage” (or alternatively “bus voltage”) refers to the electrical potential or voltage level present on a power distribution bus within a system or device. The buss voltage represents the voltage at which electrical power is supplied to various components or subsystems connected to the bus and serves as the reference voltage for the distribution of power within the system. When a power supply unit provides electrical power to an electronic device or system, the buss voltage determines the potential energy available to drive the flow of current through the system. The current drawn by the device depends on the voltage supplied by the power supply unit and the device's electrical resistance. As the current flows through the system, it performs work and consumes power.

The power supplied by the power supply unit to the electronic device or system is the product of the buss voltage and the current flowing through the system. If the buss voltage remains constant, an increase in current will result in higher power consumption by the device. Conversely, a decrease in current will lead to lower power consumption. When the local voltage is increased, assuming the current remains constant, the power delivered to the system or device also increases. By raising the voltage level, more electrical potential energy is available to drive the flow of current through the system, resulting in higher power consumption by the device. Conversely, if the local voltage is decreased while keeping the current constant, the power supplied to the system decreases. Lowering the voltage reduces the potential energy available to drive the current flow, resulting in reduced power consumption by the device.

Illustrative embodiments include monitoring a set of power supply units and disabling, upon detecting that the set of power supply units comprise a non-homogenous set of power supply units, a first power sharing circuit, the first power sharing circuit configured to perform a first load balancing function among a homogenous set of supply units. Illustrative embodiments further include activating a second power sharing circuit, the second power sharing circuit configured to perform a second load balancing function among the non-homogeneous set of power supply units.

In some embodiments, the first power sharing circuit comprises an ISHARE pin configuration, and disabling the first power sharing circuit comprises disabling the ISHARE pin functionality. In some embodiments, disabling the ISHARE pin functionality comprises creating an open circuit leading to the ISHARE pin.

Illustrative embodiments further comprise detecting that the power supply units comprise a homogenous configuration and re-activating the first power sharing circuit. In some embodiments, re-activating the first power sharing circuit comprises enabling ISHARE pin functionality.

The following description provides examples of embodiments of the present disclosure, and variations and substitutions may be made in other embodiments. Several examples will now be provided to further clarify various aspects of the present disclosure.

A computer-implemented method comprising monitoring a set of power supply units. The method further comprises disabling, upon detecting that the set of power supply units comprise a non-homogenous set of power supply units, a first power sharing circuit, the first power sharing circuit configured to perform a first load balancing function among a homogenous set of supply units. The method further comprises activating a second power sharing circuit, the second power sharing circuit configured to perform a second load balancing function among the non-homogeneous set of power supply units.

The above limitations advantageously enable monitoring the PSU units and dynamically switching between the first and second power sharing circuits based on the homogeneity of the units to provide efficient load balancing. The first power sharing circuit may be optimized for homogenous sets of PSU units, while the second circuit may be tailored for non-homogeneous configurations. This example embodiment enhances system stability by preventing power imbalances and voltage fluctuations that may arise from mismatched PSU units, which in turn improves overall system reliability. Additionally, the method contributes to optimized system performance by adapting load balancing strategies to the specific characteristics of the PSU units, thereby minimizing system down time, and resource wastage.

Example 2: The limitations of Example 1, wherein the first power sharing circuit comprises an ISHARE pin configuration, and wherein disabling the first power sharing circuit comprises disabling the ISHARE pin configuration.

The above limitations advantageously enable disabling the ISHARE pin configuration as a part of disabling the first power sharing circuit. Accordingly, the system gains enhanced control and precision in managing power distribution. Disabling the ISHARE pin configuration ensures that communication and coordination among the PSU units are effectively halted when transitioning to the second power sharing circuit for non-homogeneous sets. This prevents any residual communication through the ISHARE pin, which could potentially interfere with the operation of the second power sharing circuit. This example method enhances system stability, minimizes potential disruptions, and contributes to more efficient power management within the computing environment.

Example 3: The limitations of Example 2, wherein the disabling the ISHARE pin configuration comprises creating an open-circuit leading to an ISHARE pin.

The above limitations advantageously enable creating an open circuit leading to the ISHARE pin to ensures a complete break in the electrical connection, thereby preventing any residual signals or data transmission through the ISHARE pin. This example method of disruption eliminates the possibility of unintended communication or interference with the operation of the second power sharing circuit for non-homogeneous sets of PSU units. By creating an open circuit to disrupt the connection to the ISHARE pin, the system can ensure a reliable transition between different load balancing functions.

Example 4: The limitations of Example 1, wherein the method further comprises detecting that the power supply units comprise a second homogenous configuration and re-activating the first power sharing circuit.

The above limitations advantageously enable dynamic responses to changes in the homogeneity of the PSU units. When a second homogenous configuration is detected, re-activating the first power sharing circuit allows for optimized load balancing to this configuration. The ability to re-activate the first power sharing circuit in response to a homogenous configuration enhances the system's flexibility and responsiveness, contributing to improved power utilization and overall system efficiency in varying conditions in real-time in diverse computing environments.

Example 5: The limitations of Example 4, wherein re-activating the first power sharing circuit comprises enabling ISHARE pin functionality.

The above limitations advantageously enable a seamless transition back to utilizing the ISHARE pin for communication and coordination among a homogenous set of PSU units. Enabling ISHARE pin functionality when re-activating the first power sharing circuit ensures that the system can leverage the benefits of this communication mechanism for load balancing in homogenous configurations. By enabling ISHARE pin functionality as part of re-activating the first power sharing circuit, the system can effectively utilize this communication channel to enhance power management strategies and ensure effective load balancing in homogenous configurations.

Example 6: The limitations of Example 1, further comprises identifying a power supply unit characteristic corresponding to at least one power supply unit of the non-homogeneous set of power supply units, and wherein the second load balancing function is based at least in part on the power supply unit characteristic.

The above limitations advantageously enable incorporating identifying a power supply unit characteristic into the power management system to provide a more tailored and precise approach to load balancing in non-homogeneous configurations. Accordingly, identifying specific power supply unit characteristics allows the system to optimize the second load balancing function based on the unique attributes of the PSU units present.

Example 7: The limitations of Example 1, wherein the second load balancing function comprises determining whether at least one power supply unit provides an electrical current greater than an average electrical current provided by a remaining combination of the set of power supply units. The method further comprises decreasing, upon a determination that the at least one power supply unit provides an electrical current greater than the average electrical current provided by the remaining combination of the set of power supply units, a local voltage corresponding to the at least one power supply unit by a predefined proportional amount.

The above limitations advantageously enable assessing whether a power supply unit delivers an electrical current exceeding the average electrical current provided by the remaining combination of PSU units. By incorporating this functionality into the power management system, the method enables precise monitoring and adjustment of power distribution based on individual PSU performance. Determining if a PSU supplies a higher current than the average allows the system to identify potential imbalances and take corrective action to maintain optimal load distribution, such as by decreasing the local voltage for the PSU exceeding the average current by a predefined proportional amount ensures that power distribution remains balanced and prevents overloading of specific units. By dynamically adjusting local voltages based on individual PSU performance, the system can optimize load balancing and provide consistent and reliable power distribution within the computing environment.

Example 8: The limitations of Example 1, wherein the second load balancing function comprises determining whether at least one power supply unit provides an electrical current less than an average electrical current provided by a remaining combination of the set of power supply units. The method further comprises increasing, upon a determination that the at least one power supply unit provides an electrical current greater than the average electrical current provided by the remaining combination of the set of power supply units, a local voltage corresponding to the at least one power supply unit by a predefined proportional amount.

The above limitations advantageously enable assessing if a power supply unit supplies an electrical current lower than the average current provided by the remaining PSU units. By incorporating this functionality into the power management system, the method enables precise monitoring and adjustment of power distribution based on individual PSU performance. Identifying a PSU with lower current output than the average allows the system to detect potential underutilization and take corrective measures to ensure balanced load distribution, such as increasing the local voltage for the PSU with current below the average by a predefined proportional amount. This example method enhances system efficiency, minimizes power wastage, and promotes optimal power utilization. By dynamically adjusting local voltages based on individual PSU performance, the system can improve load balancing and provide consistent and reliable power distribution within the computing environment.

Example 9: The limitations of Example 1, further comprising detecting a failure state corresponding to at least one power supply unit of the set of power supply units. The method further comprises replacing the at least one power supply unit of the set of power supply units. The method further comprises querying the set of power supply units to determine a model type of each power supply unit.

The above limitations advantageously enable querying the PSU units during each PSU removal or insertion event to determine if the running set of PSU units is homogenous. This dynamic assessment allows the system to continuously evaluate the homogeneity of the PSU configuration in real-time, ensuring that the power management strategy remains optimized for the current set of units. By monitoring homogeneity during these events, the system can proactively detect discrepancies and non-homogeneous configurations and in the presence of non-homogeneous sets, the system can take corrective actions to mitigate risks, such as disabling specific circuits or activating alternative load balancing functions.

For the sake of clarity of the description, and without implying any limitation thereto, the illustrative embodiments are described using some example configurations. From this disclosure, those of ordinary skill in the art will be able to conceive many alterations, adaptations, and modifications of a described configuration for achieving a described purpose, and the same are contemplated within the scope of the illustrative embodiments.

Furthermore, simplified diagrams of the data processing environments are used in the figures and the illustrative embodiments. In an actual computing environment, additional structures or components that are not shown or described herein, or structures or components different from those shown but for a similar function as described herein may be present without departing the scope of the illustrative embodiments.

Furthermore, the illustrative embodiments are described with respect to specific actual or hypothetical components only as examples. Any specific manifestations of these and other similar artifacts are not intended to be limiting to the invention. Any suitable manifestation of these and other similar artifacts can be selected within the scope of the illustrative embodiments.

The examples in this disclosure are used only for the clarity of the description and are not limiting to the illustrative embodiments. Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

Furthermore, the illustrative embodiments may be implemented with respect to any type of data, data source, or access to a data source over a data network. Any type of data storage device may provide the data to an embodiment of the invention, either locally at a data processing system or over a data network, within the scope of the invention. Where an embodiment is described using a mobile device, any type of data storage device suitable for use with the mobile device may provide the data to such embodiment, either locally at the mobile device or over a data network, within the scope of the illustrative embodiments.

The illustrative embodiments are described using specific code, computer readable storage media, high-level features, designs, architectures, protocols, layouts, schematics, and tools only as examples and are not limiting to the illustrative embodiments. Furthermore, the illustrative embodiments are described in some instances using particular software, tools, and data processing environments only as an example for the clarity of the description. The illustrative embodiments may be used in conjunction with other comparable or similarly purposed structures, systems, applications, or architectures. For example, other comparable mobile devices, structures, systems, applications, or architectures therefor, may be used in conjunction with such embodiment of the invention within the scope of the invention. An illustrative embodiment may be implemented in hardware, software, or a combination thereof.

The examples in this disclosure are used only for the clarity of the description and are not limiting to the illustrative embodiments. Additional data, operations, actions, tasks, activities, and manipulations will be conceivable from this disclosure and the same are contemplated within the scope of the illustrative embodiments.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

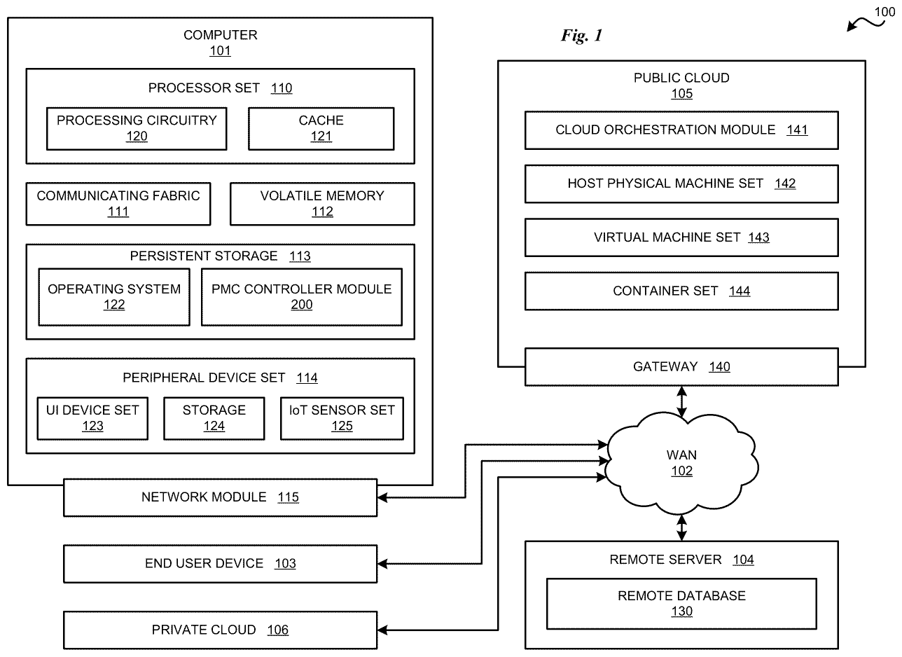

FIG. 1 depicts a block diagram of a computing environment 100. Computing environment 100 contains an example of an environment for the execution of at least some of the computer code involved in performing the inventive methods, such as an improved power management controller module 200 that is configured to selectively disable and enable power sharing amongst a non-homogenous group of power supply units. In addition to block 200, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and block 200, as identified above), peripheral device set 114 (including user interface (UI) device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144.

COMPUTER 101 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, to keep the presentation as simple as possible. Computer 101 may be located in a cloud, even though it is not shown in a cloud in FIG. 1. On the other hand, computer 101 is not required to be in a cloud except to any extent as may be affirmatively indicated.

PROCESSOR SET 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

COMMUNICATION FABRIC 111 is the signal conduction path that allows the various components of computer 101 to communicate with each other. Typically, this fabric is made of switches and electrically conductive paths, such as the switches and electrically conductive paths that make up buses, bridges, physical input/output ports and the like. Other types of signal communication paths may be used, such as fiber optic communication paths and/or wireless communication paths.

VOLATILE MEMORY 112 is any type of volatile memory now known or to be developed in the future. Examples include dynamic type random access memory (RAM) or static type RAM. Typically, volatile memory 112 is characterized by random access, but this is not required unless affirmatively indicated. In computer 101, volatile memory 112 is located in a single package and is internal to computer 101, but, alternatively or additionally, volatile memory 112 may be distributed over multiple packages and/or located externally with respect to computer 101.

PERSISTENT STORAGE 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open source Portable Operating System Interface-type operating systems that employ a kernel. The code included in block 200 typically includes at least some of the computer code involved in performing the inventive methods.

PERIPHERAL DEVICE SET 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, and haptic devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector.

NETWORK MODULE 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 012 may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 103 is any computer system that is used and controlled by an end user (for example, a customer of an enterprise that operates computer 101), and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

REMOTE SERVER 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

PUBLIC CLOUD 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Measured service: cloud systems automatically control and optimize resource use by leveraging a metering capability at some level of abstraction appropriate to the type of service (e.g., storage, processing, bandwidth, and active user accounts). Resource usage can be monitored, controlled, reported, and invoiced, providing transparency for both the provider and consumer of the utilized service.

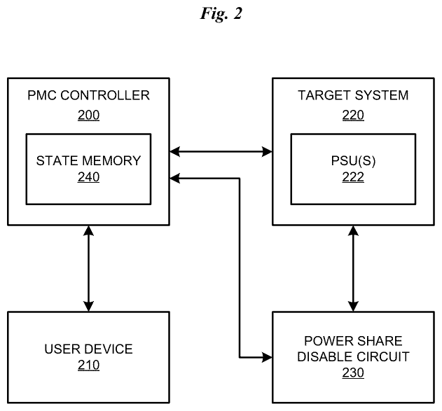

FIG. 2 depicts a block diagram of an example system environment in accordance with an illustrative embodiment. In the illustrated embodiment, system environment includes power management controller module 200 of FIG. 1.

In the illustrated embodiment, system environment includes a target system 220 controlled by power management controller module 200. In an embodiment, power management controller 200 is integrated within target system 220. In an embodiment, power management controller module 200 may be accessed via user device 210. In the illustrated embodiment, arrows between components within the system environment represent power transmission connections and/or data transmission connections. In an embodiment, the target system 220 includes a system that is supplied power by one or more power supply units. In an embodiment, the target system 220 includes a data center. In some such embodiments, the data center of target system 220 may receive power supplied from a plurality of common redundant power supplies (CRPS). In some such embodiment, the plurality of CRPS are electrically coupled to enable load sharing between the CRPS to provide electrical power to one or more devices of target system 220. For example, suppose the target system 220 includes a data processing system, then the plurality of CRPS may provide uninterrupted power delivery to the data processing system, such that in the event of a failure of one CRPS, the remaining CRPS divide the load amongst each other to prevent the system from losing power and shutting off.

In a particular embodiment, the plurality of CRPS are electrically coupled to an “ISHARE” pin. Accordingly, the ISHARE pin is used to provide a voltage reference used to balance the current output among all parallel-connected modules. Each module generates a signal proportional to its output current, which is shared across all modules via the ISHARE pin. By comparing its own output current signal with the voltage on the ISHARE pin (which represents the average current among all modules), each module adjusts its output current to achieve balance. This prevents overloading of a single module. Each power module generates an analog voltage on its ISHARE pin proportional to its output current (e.g., 1 V=10 A). All ISHARE pins of the connected modules are tied together, forming a shared signal bus. connected ISHARE pins reference the maximum current signal of all modules. Each module compares the shared ISHARE voltage (maximum current) with its own internal signal and adjusts its output current accordingly. If a module detects that its output current is lower than the maximum (as indicated by the shared ISHARE voltage), it increases its contribution.

In some instances, all CRPS of target system 220 are of the same type, specification, and/or manufacture. In those instances, the collection of CRPS can be said to constitute a homogenous group of CRPS. In ordinary circumstances, for the ISHARE pin to work effectively in a system with redundant power supplies, the power supplies must be of the same type. Accordingly, it is understood herein that the ISHARE mechanism typically relies on all power supplies having the same relationship between output current and the ISHARE voltage signal. Different types or models of power supplies may use different scaling factors or response curves for the ISHARE signal. If these do not match, the power supplies cannot accurately interpret the ISHARE signal, leading to imbalance in load sharing. For example, if one supply interprets 1 V on the ISHARE pin as 10 A of output current and another interprets it as 15 A, they will attempt to output different currents, resulting in unequal sharing.

Further, redundant power supplies should maintain a similar nominal output voltage to achieve optimal performance. ISHARE will compensate for minor differences in nominal output voltage for parallel power supplies. For example, if there is a small difference in setpoints (e.g., 12.00 V vs. 12.05 V), ISHARE will compensate for the difference and allow the power supplies to share load. However, if any power supply has a much higher setpoint than the other parallel power supplies (e.g., 12.00V vs. 12.75 V), that power supply will take on most of the load because ISHARE is no longer capable of compensating for the large voltage difference. ISHARE implementations assume that the voltage on the ISARE buss correlates to the same output current. Accordingly, for ISHARE to function as intended, using power supplies of the same type is often required since that ensures compatibility in voltage-current characteristics, and control loop behavior, resulting in stable and effective load sharing.

However, in some other instances, one or more of the CRPS may be of a different type than the remaining CRPS. In those instances, the collection of CRPS can be said to constitute a non-homogenous or heterogenous group of CRPS. In an embodiment, the PMC controller module 200 is configured to detect whether the collection of CRPS constitutes a homogenous or a non-homogenous group of CRPS. In an embodiment, if the PMC controller module 200 detects a homogenous group of CRPS, then load sharing may be achieved via utilization of the ISHARE pin. In an embodiment, if the PMC controller module 200 detects a non-homogenous group of CRPS, then the PMC controller module 200 actuates the power share disable circuit 230 to disable load sharing via the functionality of the ISHARE pin. In some such embodiments, upon disabling load sharing via the functionality of the ISHARE pin, the PMC controller module 200 proceeds to execute a power sharing function to accommodate balanced load sharing between modules of the heterogenous group of CRPS. Further, in an embodiment, the state memory 240 is configured to record a memory of various states experienced by the system, such as homogeneous identification, non-homogeneous identification, ISHARE on, and/or ISHARE off. In some embodiments, based on reading the current state of the one or more of PSUs 222 of target system 220, the PMC controller 200 performs an appropriate function, as described in greater detail herein.

In an embodiment, the power management controller 200 monitors the power distribution within the target system 220. The target system 220 comprises a set of PSU units 222 that provide power to the system. The power management controller 200 is designed to monitor the status and performance of these PSU units 222. When the power management controller 200 detects that the set of PSU units 222 is non-homogenous, the power share disable circuit 230 is activated to disable a first power sharing circuit, which is designed for load balancing among a homogenous set of PSU units. In an embodiment, the state memory 240 is utilized to store the configuration and status of the power management system. When the power share disable circuit 230 activates the second power sharing circuit for the non-homogeneous set of PSU units, the state memory 240 is updated to reflect this change. The state memory 240 maintains a record of the current power distribution configuration.

In an embodiment, the power share disable circuit 230 disrupts the connection to an ISHARE pin a power management system. In this scenario, when the power management controller determines the need to disable the power sharing circuit due to the presence of a non-homogeneous set of PSU units, the power share disable circuit 230 may be configured to create an open circuit to disrupt the connection to the ISHARE pin.

Accordingly, by intentionally creating an open circuit in the pathway that supplies a reference voltage to the ISHARE pin, the flow of current to the ISHARE pin is interrupted. This disruption effectively severs the communication link that enables the power sharing circuit to perform its load balancing function among a homogenous set of PSU units. The open circuit prevents the transmission of signals and data through the ISHARE pin, thereby disabling the operation of the power sharing circuit.

In some embodiments, the power share disable circuit 230 is configured to send a signal that interrupts the reference voltage monitoring specifically to the ISHARE pin. This interruption can be achieved through the use of electronic switches or relays that are controlled by the power share disable circuit 230. By opening or closing these switches or relays in response to the detection of a non-homogeneous set of PSU units, the power share disable circuit effectively cuts off the connection to the ISHARE pin. By controlling the connection to the ISHARE pin through the power share disable circuit 230, the power management system can transition between different power sharing methods to optimize power distribution within the system based on the characteristics of the PSU units.

In an embodiment, the power management controller 200 employs a state machine to enable or disable the ISHARE functionality based on the state of the set of PSUs, whether they correspond to a homogenous set of PSUs or a non-homogenous set of PSUs 222 within the target system 220. The state machine, which accesses the state memory 240, determines the status of the ISHARE functionality in response to the characteristics of the PSU units. When the state machine detects that the set of PSUs is homogenous, indicating that all PSU units are of the same type or have similar or compatible specifications, the state machine enables the ISHARE functionality. By accessing the state memory 240 and updating the status to reflect the enabled state of the ISHARE functionality, the state machine ensures that communication and coordination among the PSU units can occur using the ISHARE pin.

Conversely, when the state machine identifies that the set of PSUs is non-homogenous, signifying that the PSU units have varying specifications or types, the state machine disables the ISHARE functionality. In this scenario, the state machine updates the state information in the state memory 240 to indicate that the ISHARE functionality should be deactivated. By disabling the ISHARE functionality, the state machine ensures that the communication and coordination among the non-homogenous set of PSU units are managed using an alternative method, such as activating a different power sharing circuit. By dynamically enabling or disabling the ISHARE functionality based on whether the set of PSUs is homogenous or non-homogenous, the state machine optimizes the power management system's operation to suit the specific characteristics of the PSU units present.

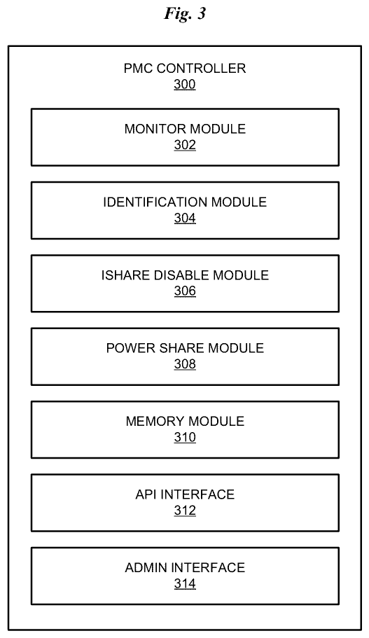

FIG. 3 depicts a block diagram of an example power management controller module 300 in accordance with an illustrative embodiment. In some embodiments, power management controller module 300 includes power management controller module 200 of FIGS. 1 and 2.

In the illustrated embodiment, the PMC controller module 300 is a software module including a plurality of interconnected software modules. In the illustrated embodiment, the PMC controller module 300 includes a monitor module 302, an identification module 304, an ISHARE disable module 306, a power share module 308, a memory module 310, an API interface module 312, and an admin interface module 314. In alternative embodiments, PMC controller module 300 can include some or all of the functionality described herein but grouped differently into one or more modules. In some embodiments, the functionality described herein is distributed among a plurality of systems, which can include combinations of software and/or hardware-based systems, for example Application-Specific Integrated Circuits (ASICs), computer programs, or smart phone applications.

In the illustrated embodiment, monitor module 302 may be configured to monitor power supplies of a target system. In an embodiment, the monitor module 302 may be configured to continuously monitor the set of power supply units (PSUs) by collecting and analyzing data to determine the homogeneity of the PSUs. In some embodiments, analyzing data may include comparing various parameters and characteristics of the PSUs to identify any differences that may indicate a non-homogenous set.

In the illustrated embodiment, identification module 304 may be configured to identify a power supply unit type corresponding to a power supply unit. In an embodiment, the identification module 304 may be configured to query each power supply unit (PSU) to determine its model type. In an embodiment, the querying process may include sending specific commands or requests to each PSU to retrieve information about its model type. In an embodiment, the identification module 304 communicates with each PSU individually, requesting data that includes details that may include, but is not limited to, the manufacturer, model number, and any other identifying information that can help determine the model type of the PSU. In an embodiment, upon receiving the responses from the PSUs, the identification module 304 analyzes the data to extract the relevant model type information. This analyzing process may include parsing the received data, comparing the received data against mapping or a database of known PSU models, and/or applying one or more algorithms to interpret the information provided by each PSU.

In the illustrated embodiment, the ISHARE disable module 306 may be configured to disable ISHARE functionality upon detecting and identifying a different power supply in comparison to the other power supplies of the target system. As discussed herein, ISHARE refers to a functionality that allows power supply units (PSUs) to share power in a coordinated and synchronized manner. Under ordinary circumstances, the ISHARE functionality enables multiple PSUs to work together to provide power to a system or device and achieve load balancing across the units. In some embodiments, PSUs may be connected to an ISHARE pin through a dedicated communication interface that facilitates the sharing of power information between the PSUs. The ISHARE pin serves as a connection point where the PSUs provide information on to companion PSUs on their output current which is used to set a target output current for all parallel power supplies. This reference voltage enables the PSUs to coordinate their operations, adjust output current levels, and ensure that the system receives a consistent and stable power supply.

In the illustrated embodiment, the ISHARE disable module may be configured to disable ISHARE functionality. In the system architecture, the ISHARE functionality can be disabled by physically opening up a circuit that connects the power supply units (PSUs) to the ISHARE pin. This process involves interrupting the electrical connection between the PSUs and the ISHARE pin, effectively preventing the exchange of data and signals related to power sharing. To disable ISHARE by opening up the circuit, the ISHARE disable module 306 actuates a mechanism such as a switch or relay can be utilized to break the electrical pathway between the PSUs and the ISHARE buss. When the circuit is open, the reference voltage from parallel power supplies to the ISHARE pin is disrupted, inhibiting the coordination and synchronization of power sharing activities among the PSUs.

Accordingly, by physically disconnecting the circuit that links the PSUs to the ISHARE pin, the system can effectively disable the ISHARE functionality. This action ensures that the PSUs no longer monitor the ISHARE voltage reference to adjust the current output, preventing coordinated power sharing among the units. By breaking the connection between the PSUs and the ISHARE pin, the system can maintain individual control over each PSU's output voltage and operation, allowing for independent functioning of the units when ISHARE functionality is not required or deemed incompatible due to heterogeneity among the PSUs.

In the illustrated embodiment, the power share module 308 may be configured to perform a power sharing routine to balance power sharing among the non-homogenous collection of power supplies upon a determination that at least one power supply is different in comparison to the other power supplies of the target system.

In the illustrated embodiment, the memory module 310 may be configured to store various states corresponding to power sharing and the power supply units (PSUs). Accordingly, this storage capability allows the system to retain information about the status of power sharing operations and the characteristics of the PSUs for reference and decision-making purposes. For example, the memory module 308 can store states such as ISHARE (ON) and ISHARE (OFF) to indicate whether the ISHARE functionality is currently enabled or disabled within the system. By recording these states, the memory module 308 tracks the operational mode of power sharing.

Further, memory module 310 may be configured to store states related to the homogeneity of the set of PSUs, such as homogenous set of PSUs (YES) and homogenous set of PSUs (NO). These states indicate whether the PSUs in the system are of the same type and compatible for power sharing or if there are differences, such as non-homogenous configurations, that may impact system performance. By storing these states in memory module 308, the system PMC controller module 300 may access and update information about power sharing conditions and PSU compatibility efficiently. In an embodiment, stored state data can be utilized by ISHARE disable module 306 to enable or disable ISHARE functionality based on PSU homogeneity.

In the illustrated embodiment, the API interface 312 may be configured to provide communication and interaction between the controller and external systems or software applications. The API interface 312 enables external entities to control and configure the power management controller by sending commands and instructions remotely, allowing for adjustments to settings, parameters, and actions without direct physical access to the controller. Additionally, the API interface allows external systems to retrieve real-time data, monitor performance metrics, and access status information from the power management controller, providing insights into power consumption, voltage levels, current readings, and temperature data for analysis and decision-making purposes.

In the illustrated embodiment, the admin interface 314 may be configured to allow a user having sufficient administrative privileges to perform various functions and/or adjust various settings associated with the PMC controller module 300. In the illustrated embodiment, an administrative user device 314 allows users with administrative privileges to perform various administrative tasks associated with power management controller module 300 as described herein. For example, in some embodiments, admin interface 314 allows an administrative user to initiate a PSU monitoring process. As another example, in some embodiments, admin interface 314 allows a user with administrative privileges to adjust parameters of a voltage trimming technique, such as modifying the range of acceptable detected values by increasing or decreasing the thresholds. Accordingly, a user having sufficient administrative privileges may modify these parameters to expand or narrow the range of acceptable detected values for voltage trimming. For instance, if the administrator wishes to allow for a wider tolerance in voltage values, they can increase the upper and lower thresholds to accommodate a broader range of voltage fluctuations without triggering corrective actions. Conversely, if a more precise voltage trimming operation is desired, the administrator can decrease the acceptable range to ensure that only voltage values within a tighter window are considered acceptable.

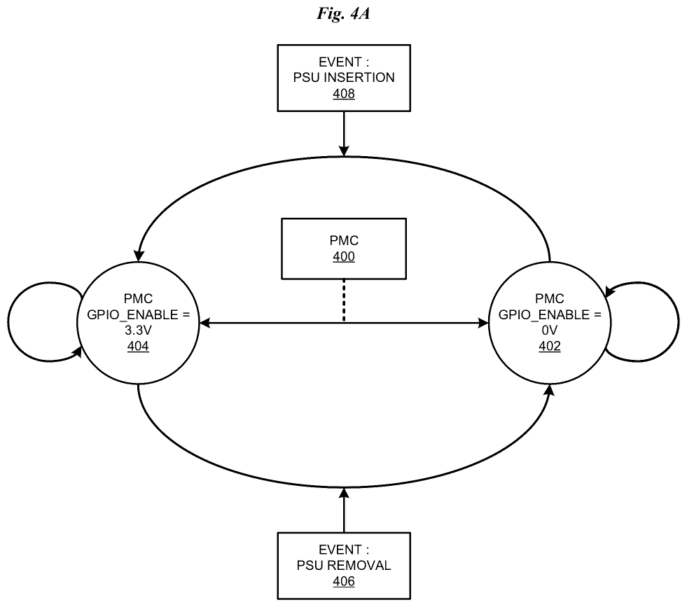

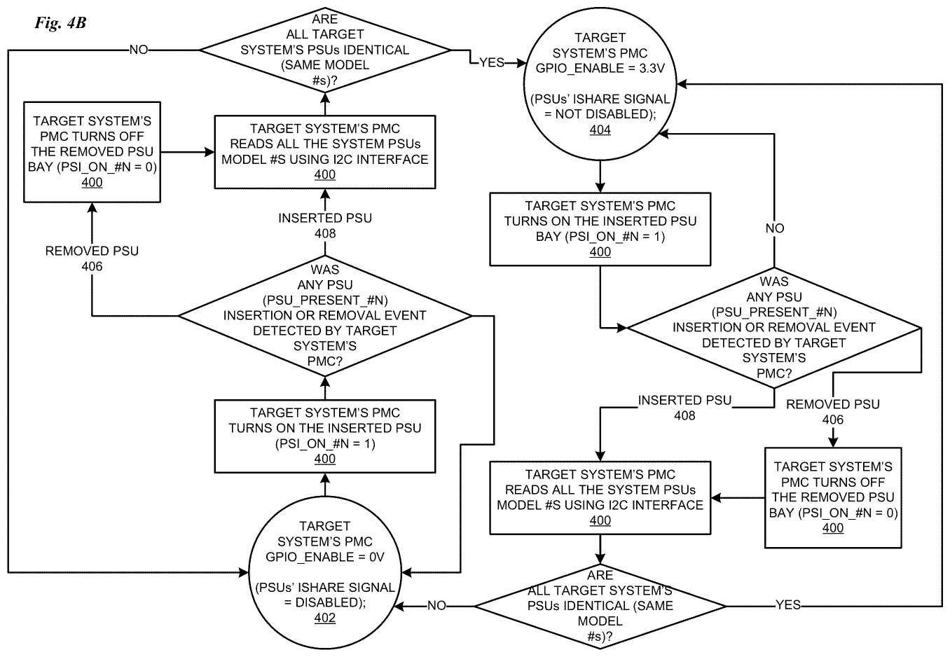

With reference to FIG. 4A, this diagram depicts a block diagram of an example state machine, in accordance with the present disclosure. In an embodiment, the state machine operates by transitioning between two states, the two states represented by block 402 and block 404. When the state machine is in the first state 402, the system may be configured to set the GPIO_ENABLE signal to a specific state that regulates power delivery within the system. This state could involve enabling or disabling certain power pathways, adjusting voltage levels, and/or activating specific power management features.

The state machine's ability to switch between these two states enables dynamic control over power management and ISHARE functionality, adapting to changing conditions and operational needs within the system. In some embodiments, the state machine responds to various internal triggers, external signals, or predefined logic, so that the GPIO_ENABLE signal is set appropriately to regulate power delivery and manage the ISHARE feature.

In the illustrated embodiment, the state machine works by transitioning between different states based on predefined conditions or events, allowing the system to keep track of when to disable and enable ISHARE functionality in response to detecting whether all power supply units (PSUs) of a set are of the same type. In the context of managing ISHARE functionality, the state machine monitors the homogeneity of the PSUs and controls the ISHARE status accordingly.

For example, initially, the state machine may be in a state where ISHARE is disabled. As the system continuously monitors the PSUs, the state machine detects whether all PSUs in the set are of the same type. If the state machine determines that the PSUs are homogeneous, indicating that they are all compatible for power sharing, it transitions to a state where ISHARE is enabled. Conversely, if the state machine detects that the PSUs are not of the same type, indicating a non-homogeneous set, it transitions to a state where ISHARE is disabled. In this state, the state machine ensures that the ISHARE functionality is deactivated to prevent incompatible PSUs from participating in power sharing, maintaining system stability and preventing potential issues that may arise from mixing different types of PSUs. By utilizing a state machine to track the homogeneity of the PSUs and control the ISHARE functionality based on this detection, the system can automate the process of enabling or disabling ISHARE in response to changes in the PSU configuration.

In an embodiment, the state machine operates based on occurrence of two events. Accordingly, a first event 406 includes removing a PSU, and a second event 408 includes inserting a PSU. The occurrence of any of the first event or the second event will trigger the PMC controller module to read the PSU model types of all of the configured PSUs of a set of PSUs. For example, suppose a first PSU is removed from the set of PSUs. The removal of the first PSU triggers the PMC module to read the model types of the existing PSUs, and if they are all the same, ISHARE functionality may remain enabled. As another example, suppose a second PSU is inserted into the configuration of the set of PSUs. The insertion of the second PSU triggers the PMC module to read the model types of the existing PSUs, and if they are all the same, ISHARE functionality may remain enabled. Contrarily, suppose PMC module 400 reads the model types of the existing PSUs, and they are not all the same, in which case the system transitions to a state where ISHARE functionality is disabled.

In an embodiment, the first event 406 includes removing a PSU from a set of PSUs. The first event 406 triggers one of the logical GPIO_ENABLE voltage states depending on determination of whether the set of PSU comprises a homogeneous or non-homogeneous set of PSUs. In an embodiment, when a PSU is removed, the ISHARE functionality stays disabled while there is a potential for a dissimilar PSU to be inserted. To transition from this state, the PMC module 400 reads all of the PSU model types of the set of PSUs to determine if all PSUs are of the same model type.

In an embodiment, the second event 408 includes inserting a PSU into the pre-existing PSU configuration. Similarly, the second event 408 triggers one of the logical GPIO_ENABLE voltage states depending on determination of whether the set of PSU comprises a homogeneous or non-homogeneous set of PSUs. Upon a determination that the set of PSU units comprises a homogeneous set of PSU units, the state machine transitions to the state enabling ISHARE functionality. Otherwise, upon a determination that the set of PSU units comprises a non-homogeneous set of PSU units, the state machine does not transition to enable ISHARE functionality, but rather remains in the ISHARE disabled state until a new event triggers reading the set of PSUs once again to once again make a determination to potentially trigger enabling ISHARE functionality. Accordingly, the PMC employs a state machine to toggle between enabled and disabled states based on reading model types of PSUs to each PSU removal or insertion event.

With reference to FIG. 4B, this figure depicts a block diagram of an example power management process in accordance with an illustrative embodiment. In some embodiments, power management controller module 200 of FIGS. 1 and 2, power management controller module 300 of FIG. 3 and/or power management controller module 400 of FIG. 4A carries out some or all operations of the process depicted by FIG. 4B. In some embodiments, target system 400 of FIG. 4B includes controller module 400 of FIG. 4A.

In an embodiment, the process begins with the PMC of the target system 400 evaluating the characteristics of the PSU of the target system 400. The PMC uses an I2C interface to read the model numbers of all connected PSUs to determine if the connected PSUs are identical to each other. If all PSUs are identical (e.g., same model numbers), then The PMC enables the GPIO (GPIO_ENABLE=3.3V), allowing the PSUs' ISHARE signal to synchronize for load sharing.

In an embodiment, when a PSU is inserted, the PMC detects the insertion event via a PSU_Present signal, resulting in the inserted PSU bay being activated (PSU_ON_#n=1). The PMC reads the updated model numbers of all PSUs via I2C to recheck if they are identical. If they are identical, the system enables synchronization (GPIO_ENABLE=3.3V). If not, synchronization is disabled (GPIO_ENABLE=0V).

When a PSU is removed, the PMC detects the removal event via a PSU_Present signal. The removed PSU bay is deactivated (PSU_ON_#n=0). The PMC reads the updated model numbers of the remaining PSUs via I2C to recheck if they are identical. If they are identical, the system enables synchronization. If not, synchronization remains disabled.

In an embodiment, the process includes a rechecking step after any PSU insertion or removal. Accordingly, after any PSU insertion or removal, the PMC loops back to check the model numbers of all PSUs. Based on the model check, the system 400 adjusts the synchronization setting and power bay states accordingly. Embodiments provide for efficiently managing power systems in environments where PSUs may need to be hot-swapped or dynamically adjusted. Embodiments of the present disclosure provide dynamic handling of PSUs responsive to live insertion and removal of PSUs by enabling or disabling PSU bays and updating synchronization settings.

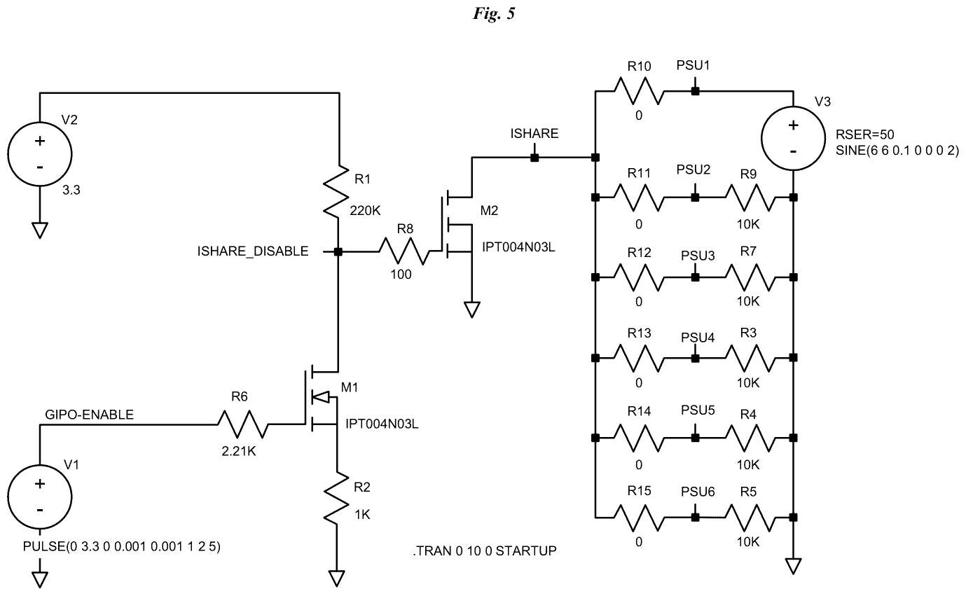

With reference to FIG. 5, this figure depicts a circuit diagram, in accordance with the present disclosure. In the illustrated embodiment, the circuit depicted includes a set of electrical components configured in a circuit to perform some or all of the operations described herein. In the illustrated embodiment, a set of transformers act as switches to transition between various states. In the illustrated embodiment, the circuit uses M1 as a control switch to enable or disable M2. When GPIO-ENABLE is active, M2 is disabled, allowing the ISHARE line to remain functional. When GPIO-ENABLE is inactive, M2 is enabled, pulling the ISHARE line to ground and disabling the ISHARE functionality. This approach provides precise control of the ISHARE feature using the GPIO-ENABLE signal.

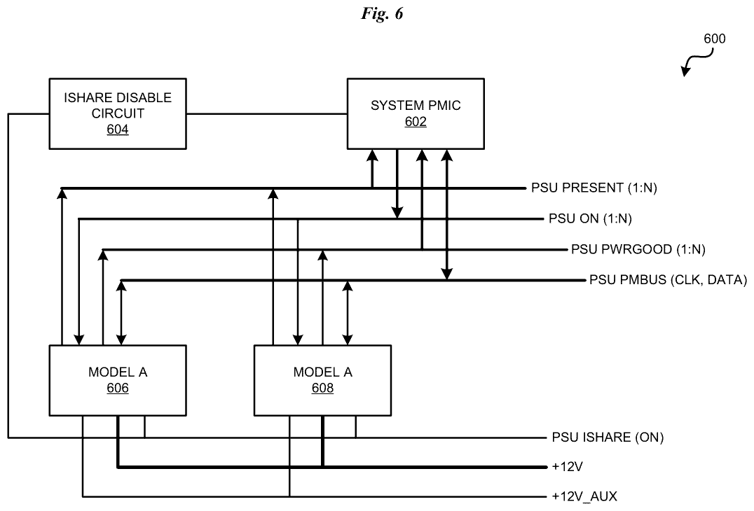

With reference to FIG. 6, this figure depicts a block diagram of an example system architecture, in accordance with the present disclosure. In some embodiments, power management controller module 200 of FIGS. 1 and 2, power management controller module 300, and/or power management controller module 300, is responsible for executing some or all of the functions described in relation to system 600.

In the illustrated embodiment, system 600 includes a system power management integrated circuit (PMIC) 602 electrically coupled to an ISHARE disable circuit 604. Further, in the illustrated embodiment, the system 600 includes a plurality of power supply units electrically coupled to a PSU ISHARE pin. In the illustrated embodiment, the plurality of power supply units includes a first power supply unit 606 and a second power supply unit 608. Although only two power supply units are shown for the sake of clarity, it is contemplated herein that the system may comprise any number of power supply units, and the number of power supply units depicted is not a limiting aspect of the present disclosure.

In the illustrated embodiment, the ISHARE disable circuit 604 is configured to monitor the plurality power supply units to detect whether the plurality of power supply units is composed of a set of homogeneous power supply units, such that each power supply unit of the set of homogeneous power supply units all corresponds to a same model type. In an instance where each power supply unit corresponds to the same model type, the ISHARE functionality is in the “ON” state, representing that ISHARE functionality is enabled to facilitate load sharing among the set of power supply units.

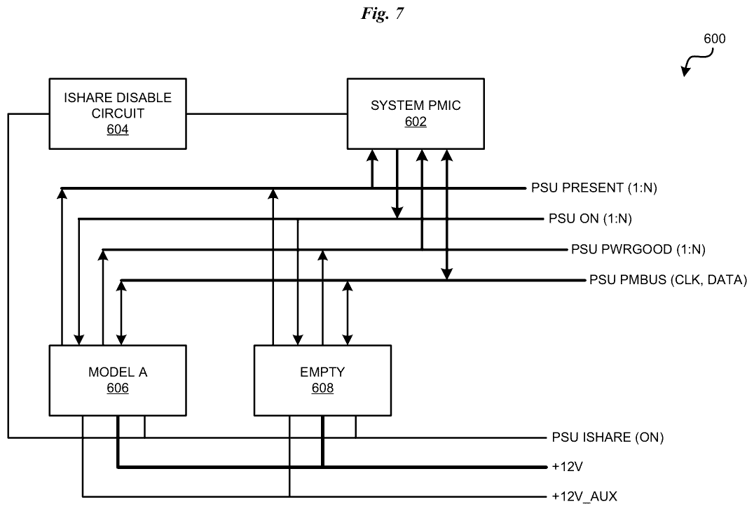

With reference to FIG. 7, this figure depicts a block diagram of an example system architecture, in accordance with the present disclosure. In the illustrated embodiment, system 600 includes the same system 600 shown in FIG. 6, except that system 600 of FIG. 7 is depicted in a different example scenario than system 600 of FIG. 6.

In the example scenario depicted by FIG. 7, the first power supply unit 602 is shown the same as it was in FIG. 6, while the second power supply unit 608 has been removed, thereby represented by an “EMPTY” state. Accordingly, this example scenario depicts a situation where one of the power supply units has been removed. For example, suppose the system PMIC 602 has detected that the second power supply unit 608 required maintenance or replacement, or otherwise corresponded to a failure state. In such an instance, the second power supply unit 608 has been removed.

Further, in the illustrated embodiment, the system PMIC 602 may be configured to actuate the ISHARE disable circuit 604 to disable ISHARE functionality upon detection of a missing or empty power supply unit. In such a case, ISHARE may be disabled, and an alternative power sharing circuit may be actuated, until. A homogenous set of PSUs is detected. For example, upon detecting that power supply unit has been removed, the system PMIC may actuate ISHARE disable circuit 604 to disable ISHARE functionality.

Further, upon the event of detecting that power supply unit has been removed, the system PMIC may be triggered to determine whether the set of PSU units comprises a homogenous set of PSU units. Upon a determination that the set of PSU units comprises a homogenous set of PSU units, the PMIC 602 activates ISHARE functionality, which is depicted as “ISHARE (ON)”.

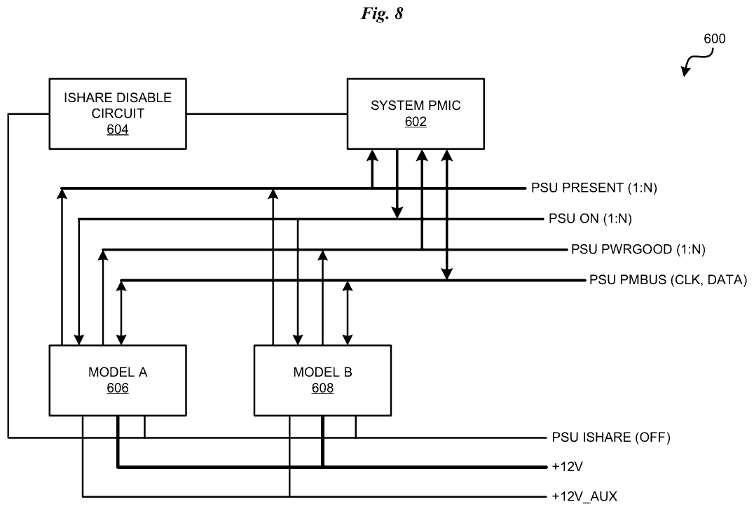

With reference to FIG. 8, this figure depicts a block diagram of an example system architecture, in accordance with the present disclosure. In the illustrated embodiment, system 600 includes the same system 600 shown in FIGS. 6 and 7, except the system 600 is depicted in a different example scenario than system 600 of FIGS. 6 and 7.

In the illustrated embodiment, the first power supply unit 606 is shown corresponding to a first model type (“Model A”), whereas the second power supply unit 608 is shown corresponding to a second model type (“Model B”). In such a scenario, the set of power supply units is composed of a non-homogenous or heterogenous set of power supply units, such that the first power supply unit 606 is a different model than the second power supply unit 608.

In the illustrated embodiment, the PSU ISHARE remains in the “OFF” state, representing that the PSU ISHARE functionality is presently disabled. In such an instance, the system PMIC 602 may be configured to enable an alternative power sharing function to provide load balancing between the first power supply unit 606 and the second power supply unit 608. In an embodiment, the alternative power sharing function may be accomplished as follows.

In an embodiment, the system PMIC 602 measures the current in each power supply unit. Further, the PMIC 602 calculates an average current of the previously existing power supply unit. Further, the system PMIC 602 determines whether the current of the new power supply unit is within a predefined threshold amount (e.g., 5%) of the average current. For example, if the current is within 5% of the average current, no adjustments are made.

However, in the event that the PSU current is not within 5% of the average current, then the PMIC 602 proceeds to measure the local PSU voltage and buss voltage. Further, the PMIC 602 proceeds to calculate the difference between the local PSU voltage and the buss voltage. Further, the PMIC 602 determines whether the current provided by the new PSU is too high. If the current is too high, the PMIC 602 decreases the local voltage by 90% of the voltage difference. Otherwise, if the current is not too high, the PMIC 602 increases the local voltage by 90% of the voltage difference.

Further, the PMIC 602 again measures the current in each PSU, calculates the average current on old PSUs, and determines if the new PSU is within 5% of the average current. Depending on the determination, the process continues iteratively until the new PSU has reached within 5% of the average current, upon which the routine terminates. Although certain percentages and proportions have been discussed by way of example, it is contemplated herein that the exact values, percentages, and proportional increases/decreases discussed may be implementation specific, and may be adjusted by a user depending upon user and/or application preference and/or suitability.

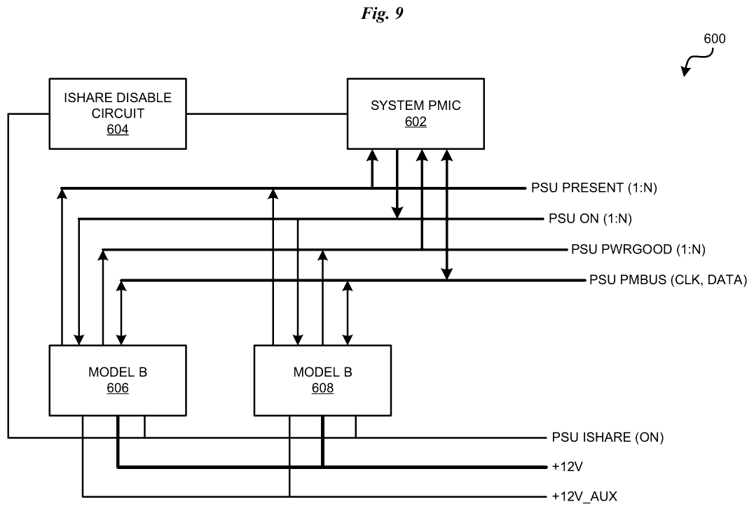

With reference to FIG. 9, this figure depicts a block diagram of an example system architecture, in accordance with the present disclosure. In the illustrated embodiment, system 600 includes the same system 600 shown in FIGS. 6, 7, and 8, except the system 600 of FIG. 9 is depicted in a different example scenario than system 600 of FIGS. 6, 7, and 8.

In the illustrated embodiment, the first power supply unit 602 and the second power supply unit 604 are shown as the same model type (Model B). In such a scenario, the ISHARE disable circuit 604 re-activates ISHARE functionality. Accordingly, the PMIC 602 may be configured to continuously monitor the set of power supply units to determine whether the power supply units all correspond to the same model type. In an embodiment, each time an event occurs, such as removing or inserting a PSU, the PMIC 602 reads the set of PSU units to determine the model type of each PSU. In an instance that each power supply unit of the set of power supply units is of the same model type, the ISHARE disable circuit 604 may cause the ISHARE to be re-activated, and normal operation of ISHARE may be resumed.

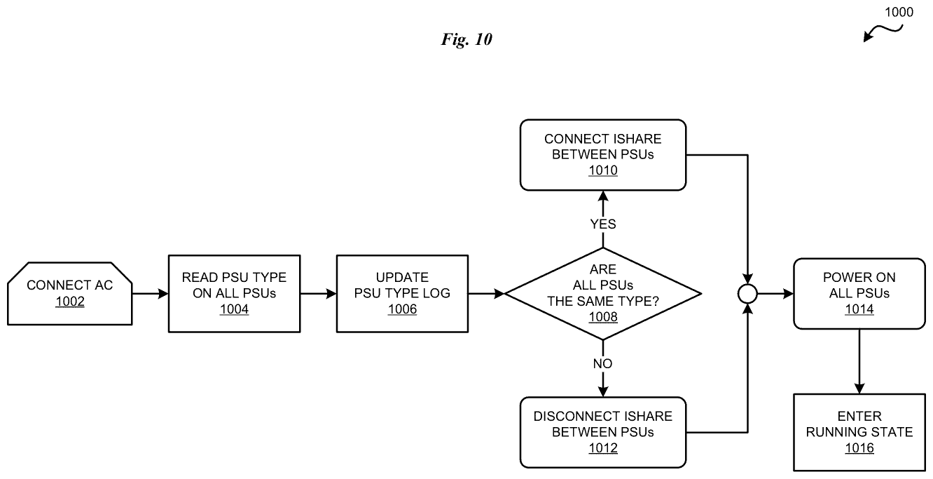

With reference to FIG. 10, this figure depicts a flowchart of an example service routine, in accordance with an illustrative embodiment. In some embodiments, power management controller module 200 of FIGS. 1 and 2, power management controller module 300 of FIG. 3 and/or power management controller module 400 of FIGS. 4A and 4B carries out some or all operations of the steps of process 1000.

In an embodiment, at block 1002, the system is initially connected to an alternating current (AC) power source to supply power to the components. In an embodiment, at block 1004, the system reads the types of all connected PSUs to determine their specifications. In an embodiment, at block 1006, the system updates a log to record the types of the PSUs that are currently connected. In an embodiment, at block 1008, the system reads and determines whether all the connected PSUs are of the same type (e.g., same model or specifications). In an embodiment, at block 1010, upon a determination that all PSUs are of the same type, the system connects ISHARE between the PSUs. In an embodiment, at block 1012, upon a determination that all PSUs are not of the same type, the system disconnects ISHARE between the PSUs. In an embodiment, at step 1014, once PSUs are properly configured (either connected or disconnected via ISHARE), the system powers on all PSUs. In an embodiment, at block 1016, system transitions into a normal operating or “running” state, indicating that the PSUs are functioning and ready to deliver power to the connected devices.

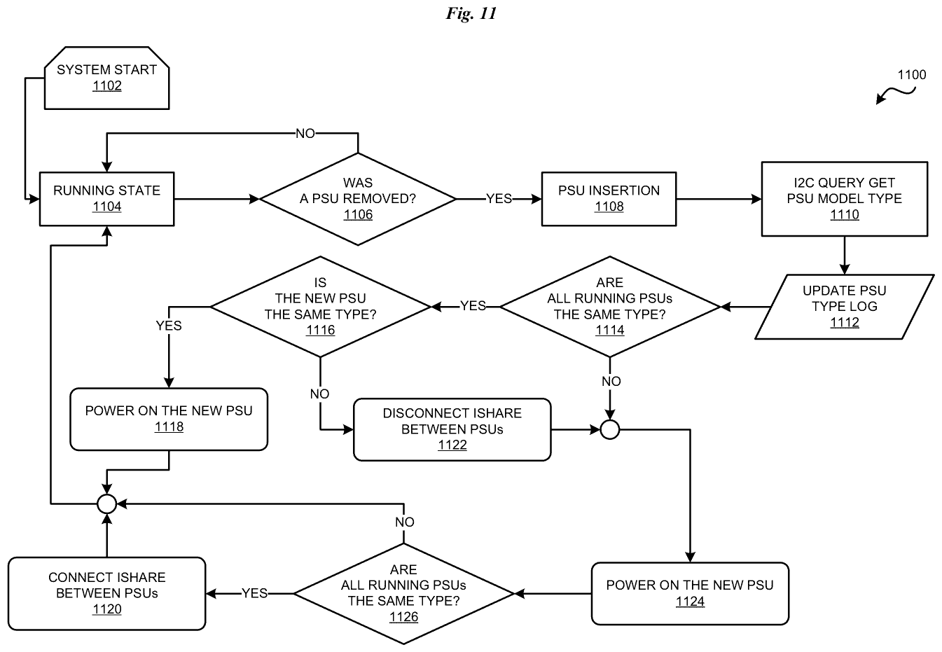

With reference to FIG. 11, this figure depicts a flowchart of an example process for power management, in accordance with an illustrative embodiment. In some embodiments, power management controller module 200 of FIGS. 1 and 2, and/or power management controller module 300 carries out some or all operations of the steps of process 1000.

In an embodiment, at block 1102, the system is started or initialized. In an embodiment, at block 1104, the system is experiencing a running state. In an embodiment, at block 1104, the system detects whether a PSU was removed. In an embodiment, at block 1108, upon removal of a PSU, the process includes inserting a new PSU into the present PSU configuration. In an embodiment, at block 1110, the process performs an I2C query to obtain the model type of each PSU of the present PSU configuration. In an embodiment, at block 1112, the process includes updating a PSU type log to incorporate information obtained from the I2C query regarding model type of each PSU. In an embodiment, at block 1114, the process determines whether all running PSU units are of the same type. In an embodiment, at block 1116, upon a determination that all running PSU units are of the same type, the process determines whether the new PSU is of the same type. In an embodiment, at block 1118, upon a determination that the new PSU is of the same type as the existing running PSUs, the process powers on the new PSU. In an embodiment, upon powering on the new PSU, the process resumes at running state 1104.

In an embodiment, at block 1122, upon a determination that the new PSU unit is not the same type as the running PSUs, the process includes disconnecting ISHARE between the PSUs. In an embodiment, at block 1124, the process powers on the new PSU. In an embodiment, at block 1124, upon a determination that the running PSUs are not all of the same type (block 1114, the process powers of the new PSU.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “illustrative” is used herein to mean “serving as an example, instance or illustration.” Any embodiment or design described herein as “illustrative” is not necessarily to be construed as preferred or advantageous over other embodiments or designs. The terms “at least one” and “one or more” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

Thus, a computer implemented method, system or apparatus, and computer program product are provided in the illustrative embodiments for managing participation in online communities and other related features, functions, or operations. Where an embodiment or a portion thereof is described with respect to a type of device, the computer implemented method, system or apparatus, the computer program product, or a portion thereof, are adapted or configured for use with a suitable and comparable manifestation of that type of device.

Where an embodiment is described as implemented in an application, the delivery of the application in a Software as a Service (SaaS) model is contemplated within the scope of the illustrative embodiments. In a SaaS model, the capability of the application implementing an embodiment is provided to a user by executing the application in a cloud infrastructure. The user can access the application using a variety of client devices through a thin client interface such as a web browser (e.g., web-based e-mail), or other light-weight client-applications. The user does not manage or control the underlying cloud infrastructure including the network, servers, operating systems, or the storage of the cloud infrastructure. In some cases, the user may not even manage or control the capabilities of the SaaS application. In some other cases, the SaaS implementation of the application may permit a possible exception of limited user-specific application configuration settings.

Embodiments of the present invention may also be delivered as part of a service engagement with a client corporation, nonprofit organization, government entity, internal organizational structure, or the like. Aspects of these embodiments may include configuring a computer system to perform, and deploying software, hardware, and web services that implement, some or all of the methods described herein. Aspects of these embodiments may also include analyzing the client's operations, creating recommendations responsive to the analysis, building systems that implement portions of the recommendations, integrating the systems into existing processes and infrastructure, metering use of the systems, allocating expenses to users of the systems, and billing for use of the systems. Although the above embodiments of present invention each have been described by stating their individual advantages, respectively, present invention is not limited to a particular combination thereof. To the contrary, such embodiments may also be combined in any way and number according to the intended deployment of present invention without losing their beneficial effects.

What is claimed is:

1. A computer-implemented method comprising:
monitoring a set of power supply units;
disabling, upon detecting that the set of power supply units comprise a non-homogenous set of power supply units, a first power sharing circuit, the first power sharing circuit configured to perform a first load balancing function among a homogenous set of supply units; and
activating a second power sharing circuit, the second power sharing circuit configured to perform a second load balancing function among the non-homogeneous set of power supply units.

2. The computer-implemented method of claim 1, wherein the first power sharing circuit comprises an ISHARE pin configuration, and wherein disabling the first power sharing circuit comprises disabling the ISHARE pin configuration.

3. The computer-implemented method of claim 2, wherein the disabling the ISHARE pin configuration comprises creating an open-circuit leading to an ISHARE pin.

4. The computer-implemented method of claim 1, the method further comprises detecting that the power supply units comprise a second homogenous configuration and re-activating the first power sharing circuit.

5. The computer-implemented method of claim 4, wherein re-activating the first power sharing circuit comprises enabling ISHARE pin functionality.

6. The computer-implemented method of claim 1, further comprises identifying a power supply unit characteristic corresponding to at least one power supply unit of the non-homogeneous set of power supply units, and wherein the second load balancing function is based at least in part on the power supply unit characteristic.

7. The computer-implemented method of claim 1, wherein the second load balancing function comprises:
determining whether at least one power supply unit provides an electrical current greater than an average electrical current provided by a remaining combination of the set of power supply units; and
decreasing, upon a determination that the at least one power supply unit provides an electrical current greater than the average electrical current provided by the remaining combination of the set of power supply units, a local voltage corresponding to the at least one power supply unit by a predefined proportional amount.

8. The computer-implemented method of claim 1, wherein the second load balancing function comprises:
determining whether at least one power supply unit provides an electrical current less than an average electrical current provided by a remaining combination of the set of power supply units; and
increasing, upon a determination that the at least one power supply unit provides an electrical current greater than the average electrical current provided by the remaining combination of the set of power supply units, a local voltage corresponding to the at least one power supply unit by a predefined proportional amount.

9. The computer-implemented method of claim 1, further comprising:
detecting a failure state corresponding to at least one power supply unit of the set of power supply units;
replacing the at least one power supply unit of the set of power supply units; and
querying the set of power supply units to determine a model type of each power supply unit.

10. A computer program product comprising one or more computer readable storage media, and program instructions collectively stored on the one or more computer readable storage media, the program instructions executable by a processor to cause the processor to perform operations comprising:
monitoring a set of power supply units;
disabling, upon detecting that the set of power supply units comprise a non-homogenous set of power supply units, a first power sharing circuit, the first power sharing circuit configured to perform a first load balancing function among a homogenous set of supply units; and
activating a second power sharing circuit, the second power sharing circuit configured to perform a second load balancing function among the non-homogeneous set of power supply units.

11. The computer program product of claim 10, wherein the stored program instructions are stored in a computer readable storage device in a data processing system, and wherein the stored program instructions are transferred over a network from a remote data processing system.

12. The computer program product of claim 10, wherein the stored program instructions are stored in a computer readable storage device in a server data processing system, and wherein the stored program instructions are downloaded in response to a request over a network to a remote data processing system for use in a computer readable storage device associated with the remote data processing system, further comprising:
program instructions to meter use of the program instructions associated with the request; and
program instructions to generate an invoice based on the metered use.

13. The computer program product of claim 10, further comprises detecting that the set of power supply units comprises a second homogenous configuration and re-activating the first power sharing circuit.

14. The computer program product of claim 10, wherein the second load balancing function comprises:
determining whether at least one power supply unit provides an electrical current greater than an average electrical current provided by a remaining combination of the set of power supply units; and
decreasing, upon a determination that the at least one power supply unit provides an electrical current greater than the average electrical current provided by the remaining combination of the set of power supply units, a local voltage corresponding to the at least one power supply unit by a predefined proportional amount.

15. The computer program product of claim 10, wherein the second load balancing function comprises:
determining whether at least one power supply unit provides an electrical current less than an average electrical current provided by a remaining combination of the set of power supply units; and
increasing, upon a determination that the at least one power supply unit provides an electrical current greater than the average electrical current provided by the remaining combination of the set of power supply units, a local voltage corresponding to the at least one power supply unit by a predefined proportional amount.

16. The computer program product of claim 10, further comprising:
detecting a failure state corresponding to at least one power supply unit of the set of power supply units;
replacing the at least one power supply unit of the set of power supply units; and
querying the set of power supply units to determine a model type of each power supply unit.

17. A computer system comprising a processor and one or more computer readable storage media, and program instructions collectively stored on the one or more computer readable storage media, the program instructions executable by the processor to cause the processor to perform operations comprising:
monitoring a set of power supply units;
disabling, upon detecting that the set of power supply units comprise a non-homogenous set of power supply units, a first power sharing circuit, the first power sharing circuit configured to perform a first load balancing function among a homogenous set of supply units; and
activating a second power sharing circuit, the second power sharing circuit configured to perform a second load balancing function among the non-homogeneous set of power supply units.

18. The computer system of claim 17, wherein the second load balancing function comprises:
determining whether at least one power supply unit provides an electrical current greater than an average electrical current provided by a remaining combination of the set of power supply units; and
decreasing, upon a determination that the at least one power supply unit provides an electrical current greater than the average electrical current provided by the remaining combination of the set of power supply units, a local voltage corresponding to the at least one power supply unit by a predefined proportional amount.

19. The computer system of claim 17, wherein the second load balancing function comprises:
determining whether at least one power supply unit provides an electrical current less than an average electrical current provided by a remaining combination of the set of power supply units; and
increasing, upon a determination that the at least one power supply unit provides an electrical current greater than the average electrical current provided by the remaining combination of the set of power supply units, a local voltage corresponding to the at least one power supply unit by a predefined proportional amount.

20. The computer system of claim 17, further comprising:
detecting a failure state corresponding to at least one power supply unit of the set of power supply units;
replacing the at least one power supply unit of the set of power supply units; and
querying the set of power supply units to determine a model type of each power supply unit.
